(19) United States
(12) Patent Application Publication
(10) Pub. No.: US 2008/0308864 A1
(43) Pub. Date: Dec. 18, 2008

(54) ASYMMETRICAL MOS TRANSISTOR AND FABRICATION METHOD THEREOF AND DEVICES USING THE SAME

(75) Inventor: Hung-Sung Lin, Miaoli County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/764,363

(22) Filed: Jun. 18, 2007

(51) Int. Cl. H01L 21/02; H01L 29/78

(52) U.S. Cl. 257/344; 438/286; 257/E21.196; 257/E29.152

(57) ABSTRACT

An asymmetrical MOS transistor having characteristics of a variable resistor and a transistor is provided. The asymmetrical MOS transistor comprises a substrate, a gate structure, a pair of spacers, a pair of offset spacers, a source region, a drain region, and an extension region. Herein, the extension region is disposed in the substrate under apportion of the gate structure and one of the pair of spacers. And, the extension region connects one of the source region or the drain region. The extension region is a heavily doping region.

### BACKGROUND OF THE INVENTION

1. Field of the Invention

The present invention relates to an integrated circuit device and a method for fabricating the same. More particularly, the present invention relates to an asymmetrical metal-oxide-semiconductor (MOS) transistor, a fabrication method thereof, and an inverter and a memory structure using the same.

2. Description of Related Art

In recent years, the rapid development in information and communication technology and the growing popularity of information media such as computers result in the advancement of semiconductor devices. Usually, a plurality of logic circuit devices are fabricated into one single electronic product. Examples of logic circuit devices such as active matrix devices or passive matrix devices include transistors, resistors and capacitors. The types of logic circuit devices found in an electronic product depend on the specific type of logic function desired. Herein, a transistor is a semiconductor device, which is used for functions such as amplification, oscillation, and switching. Resistors vary the resistance by moving continuously in order to adjust the current or the voltage within the circuit.

Conventionally, the size of a device is miniaturized to provide a higher level of integration. However, the size of a device cannot be unlimitedly miniaturized to further reduce the size of a electronic product. Hence, it has become a common goal in the integrated circuit industry to fabricate novel semiconductor devices that overcome the aforementioned issues and develop new integrated circuit fabrication techniques.

### SUMMARY OF THE INVENTION

Accordingly, the present invention provides an asymmetrical MOS transistor that helps the miniaturization of electronic products and improves the level of integration for the overall fabrication process.

Also, the present invention provides a method for fabricating an asymmetrical MOS transistor having the characteristics of a variable resistor and a transistor using the MOS fabrication process.

Further, the present invention provides an inverter that uses the asymmetrical MOS transistor of the present invention to reduce current leakage and resistance of devices and increase ion gain.

Moreover, the present invention provides a static random access memory (SRAM) that uses the asymmetrical MOS transistor of the present invention to reduce current leakage and resistance of devices and increase ion gain.

Additionally, the present invention provides a static random access memory circuit that uses the asymmetrical MOS transistor of the present invention to reduce current leakage and resistance of devices and increase ion gain.

The present invention provides an asymmetrical MOS transistor having characteristics of a variable resistor and a transistor. This asymmetrical MOS transistor includes a substrate, a gate structure, a pair of spacers, a pair of offset spacers, a source region, a drain region, and an extension region. Herein, the gate structure is disposed on the substrate. The gate structure includes a gate and a gate dielectric layer disposed between the gate and the substrate. The spacers are respectively disposed on the sidewalls of the gate structure. The offset spacers are respectively disposed between the gate structure and the spacers. The source and the drain region are respectively disposed in the substrate on the sides of the spacers. The extension region is disposed in the substrate, and below one of the offset spacers and a portion of the gate structure, connecting to one of the source and the drain region. Specifically, the extension region is a heavily doping region.

According to the embodiment of the present invention, the doping concentration of the extension region is between 5×10¹⁴ atoms/cm³ to 10¹⁸ atoms/cm³.

According to the embodiment of the present invention, the aforementioned offset spacers are, for example, silicon oxide layers, silicon nitride layers or oxide/nitride/oxide (ONO) layers.

The present invention provides another method for fabricating an asymmetrical MOS transistor. The asymmetrical MOS transistor has characteristics of a variable resistor and a transistor. According to this method, a gate structure is formed on a substrate. The gate structure includes a gate and a gate dielectric layer formed between the gate and the substrate. Next, a pair of offset spacers is formed on the sidewalls of the gate structure and the bottom of one of the offset spacers extends to cover a portion of the surface of the substrate. Afterward, a first ion implantation process is performed to form an extension region in the substrate on the sidewalls of the other offset spacer. Thereafter, a pair of spacers is formed on the gate structure to cover the offset spacers. Subsequently, a second ion implantation process is performed to form a source and a drain region and one of the source and the drain region connects to the extension region. Herein, the extension region is a heavily doping region.

According to the embodiment of the present invention, the method for forming the aforementioned offset spacer is, for example, compliantly forming an offset spacer material layer on the substrate and the gate structure. Next, a photoresist layer is formed to cover a portion of the offset spacer material layer on one side of the gate structure and above the gate structure. Afterward, an etch-back process is performed to remove the photoresist layer and a portion of the offset spacer material layer until the gate and the surface of the substrate are exposed to form the offset spacers.

According to the embodiment of the present invention, the doping concentration of the extension region is between 5×10¹⁴ atoms/cm³ to 10¹⁸ atoms/cm³.

According to the embodiment of the present invention, the aforementioned offset spacers are, for example, silicon oxide layers, silicon nitride layers or oxide/nitride/oxide (ONO) layers.

The present invention provides an inverter comprising a P-type transistor and an N-type transistor. Herein the N-type transistor and the P-type transistor are serially connected. Further, at least the P-type transistor or the N-type transistors is the aforementioned asymmetrical MOS transistor.

The present invention also provides a static random access memory (SRAM) including two access transistors, two drive transistors and two load transistors. Herein, the load transistors are the aforementioned asymmetrical MOS transistors.

According to the embodiment of the present invention, the aforementioned load transistors are P-type MOS transistors, the access transistors are N-type MOS transistors, and the drive transistors are N-type MOS transistors.

The present invention provides a static random access memory circuit. This circuit includes a first word line, a second word line, a first bit line, a second bit line, a first access transistor, a second access transistor, a first load transistor, a first drive transistor, a second load transistor and a second drive transistor. The gate of the first access transistor is coupled to the first word line and the first S/D region of the first access transistor is coupled to the first bit line. The gate of the second access transistor is coupled to the second word line and the first S/D region of the second access transistor is coupled to the second bit line. The first load transistor is the aforementioned asymmetrical MOS transistor. The gate of the first load transistor is coupled to the second S/D region of the second access transistor. The first S/D region of the first load transistor is coupled to a first voltage. The second S/D region of the first load transistor is coupled to the second S/D region of the first access transistor. The gate of the first drive transistor is coupled to the second S/D region of the second access transistor. The first S/D region of the first drive transistor is coupled to the second S/D region of the first access transistor. The second S/D region of the first drive transistor is coupled to a second voltage. The second load transistor is the aforementioned asymmetrical MOS transistor. The gate of the second load transistor is coupled to the second S/D region of the first access transistor. The first S/D region of the second load transistor is coupled to the first voltage. The second S/D region is coupled to the second S/D region of the second access transistor. The gate of the second drive transistor is coupled to the second S/D region of the first access transistor. The first S/D region of the second drive transistor is coupled to the second S/D region of the second access transistor. The second S/D region is coupled to the second voltage. According to the embodiment of the present invention, the first load transistor and the second load transistor are P-type MOS transistors. The first access transistor and the second access transistor are N-type MOS transistors. The first drive transistor and the second drive transistor are N-type MOS transistors. According to the embodiment of the present invention, the first voltage is the power source voltage and the second voltage is the ground voltage.

The asymmetrical MOS transistor of the present invention has characteristics of a variable resistor and a transistor, which helps the miniaturization of electronic products and improves the level of integration. Further, an MOS fabrication process is used to manufacture the asymmetrical MOS transistor of the present invention. In another aspect, the asymmetrical MOS transistor of the present invention can be used in devices such as inverters and static random access memories and the asymmetrical MOS transistor of the present invention can reduce current leakage and resistance of devices and increase ion gain.

In order to make the above and other objects, features and advantages of the present invention more comprehensible, several embodiments accompanied with figures are described in detail below.

### BRIEF DESCRIPTION OF THE DRAWINGS

FIG. 1 is a schematic cross-sectional view illustrating an asymmetrical MOS transistor according to one embodiment of the present invention.

FIG. 2 and FIG. 3 show the relationships between the voltage and the current measured during electrical tests for the asymmetrical MOS transistor.

FIGS. 4A through 4F are schematic cross-sectional views illustrating the steps for fabricating an asymmetrical MOS transistor according to one embodiment of the present invention.

FIG. 5 is a schematic cross-sectional view illustrating an inverter according to one embodiment of the present invention.

FIG. 6 is a schematic cross-sectional view illustrating an inverter according to another embodiment of the present invention.

FIG. 7 is a schematic cross-sectional view illustrating a SRAM according to an embodiment of the present invention.

FIG. 8 is a schematic circuit diagram of a SRAM according to an embodiment of the present invention.

### DESCRIPTION OF EMBODIMENTS

To provide a higher level of integration in the semiconductor fabrication process and develop new techniques in the integrated circuit industry, the present invention provides an asymmetrical metal-oxide-semiconductor (MOS) transistor. Particularly, the asymmetrical MOS transistor of the present invention has characteristics of a variable resistor and a transistor.

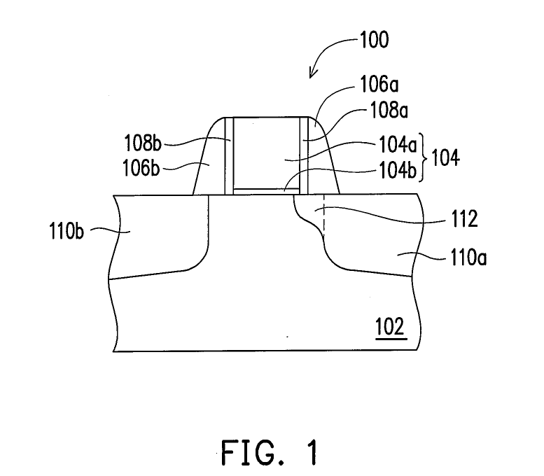

FIG. 1 is a schematic cross-sectional view illustrating an asymmetrical MOS transistor according to one embodiment of the present invention.

Referring to FIG. 1, an asymmetrical MOS transistor 100 includes a substrate 102, a gate structure 104, spacers 106a and 106b, offset spacers 108a and 108b, a drain region 110a, a source region 110b, and an extension region 112. Herein, the substrate 102 is, for example, a silicon substrate. In this embodiment, the substrate 102 is, for example, a P-type substrate. The gate structure 104 composed of a gate 104a and a gate dielectric layer 104b is disposed on the substrate 102. The material used for fabricating the gate 140a is, for example, doped polysilicon or other suitable material. The gate dielectric layer 104b is disposed between the substrate 102 and the gate 104a, and the material used for fabricating the gate dielectric layer 104b is, for example, silicon oxide or other suitable material.

The spacers 106a and 106b are respectively disposed on the sidewalls of the gate structure 104. The material used for fabricating the spacers 106a and 106b is, for example, silicon nitride or other suitable material. The offset spacer 108a is disposed between the gate structure 104 and the spacer 106a, and the offset spacer 108b is disposed between the gate structure 104 and the spacer 106b. The offset spacers 108a and 108b are, for example, silicon oxide layers, silicon nitride layers or other suitable dielectric material layers. Certainly, the offset spacers 108a and 108b can be, for example, oxide/nitride/oxide (ONO) layers.

The drain region 110a is disposed in the substrate 102 on the sides of the spacer 106a, and the source region. 110b is disposed in the substrate 102 on the sides of the spacer 106b. In the present embodiment, the drain region 110a and the source region 110b are, for example, doping regions doped with N-type dopant, and the N-type dopant used is, for example, phosphorous (P) or arsenic (As).

The asymmetrical MOS transistor 100 further includes one extension region 112. The extension region 112 is disposed in the substrate 102 and below one of the offset spacers 108a and 108b and a portion of the gate structure 104, connecting to one of the drain region 110a and the source region 110b. In this embodiment, the extension region connecting to the drain region 110a. The extension region 112, the drain region 110a and the source region 110b have the same dopant type, which is N-type dopant. Further, the doping concentration of the extension region 112 is between 5×10¹⁴ atoms/cm³ to 10¹⁸ atoms/cm³.

In the above-mentioned embodiment, the substrate 102 is a P-type substrate and the dopant type of the extension region 112, the drain region 110a and the source region 110b are n-type dopant, which are examples to illustrate the present invention; however, the invention is not limited to these examples. In one embodiment, the substrate 102 can be a N-type substrate, and the dopant type of the extension region 112 and the drain region 110a and the source region 110b are p-type dopant, and the extension region 112 is a p⁺ doping region.

Since the asymmetrical MOS transistor of the present invention has characteristics of a variable resistor and a transistor, the asymmetrical MOS transistor can be used in a variety of electronic products where packaging of variable resistors and transistors is desired in order to help miniaturization of electronic products and provide a higher level of integration in the semiconductor fabrication process.

In another aspect, since the asymmetrical MOS transistor of the present invention has characteristics of a variable resistor, when the asymmetrical MOS transistor is used as a transistor, current leakage and resistance of devices can be reduced and ion gain can be increased.

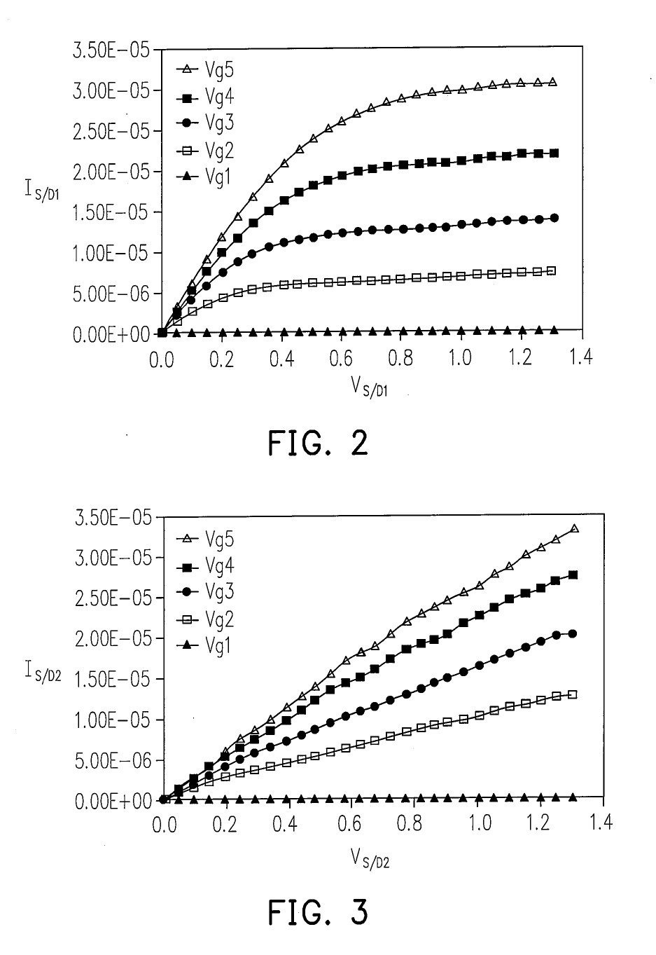

To demonstrate the effects of the present invention, the asymmetrical MOS transistor 100 of FIG. 1 is used to perform electrical tests and the results of the tests are shown in FIG. 2 and FIG. 3.

FIG. 2 shows the relationship between the voltage and the current measured when a drain voltage (V_{D}) is applied to the drain region 110a, a gate voltage (V_{g}) is applied to the gate 104a, and the source region 110b and the substrate 102 are grounded. In FIG. 2, under different gate voltages, V_{g1}, V_{g2}, V_{g3}, V_{g4}, and V_{g5}, as V_{D} gradually increase, I_{D} gradually increases from 0 and converges to a fixed value. According to the current-voltage (I-V) characteristics shown in FIG. 2, the asymmetrical MOS transistor of the present invention can function as a transistor.

FIG. 3 shows a relationship between the voltage and the current measured when a source voltage (V_{S}) is applied to the source region 110b, a gate voltage (V_{g}) is applied to the gate 104a, and the S/D region 110a and the substrate 102 are grounded. In FIG. 3, at/under different gate voltages, V_{g1}, V_{g2}, V_{g3}, V_{g4}, and V_{g5}, as V_{S} gradually increase, I_{S} gradually increases. Further, the ratio of voltage to current is a constant. Moreover, through controlling the size of V_{g}, the resistance of the asymmetrical MOS transistor 100 can be adjusted accordingly. According to the current-voltage (I-V) characteristics shown in FIG. 3, the asymmetrical MOS transistor of the present invention can function as a variable resistor.

According to the above-mentioned electrical tests, the asymmetrical MOS transistor of the present invention indeed has the characteristics of a transistor and a variable resistor.

Next, an embodiment is described in detail below to illustrate the method for fabricating the asymmetrical MOS transistor of the present invention; however, the invention is not limited to this fabrication method.

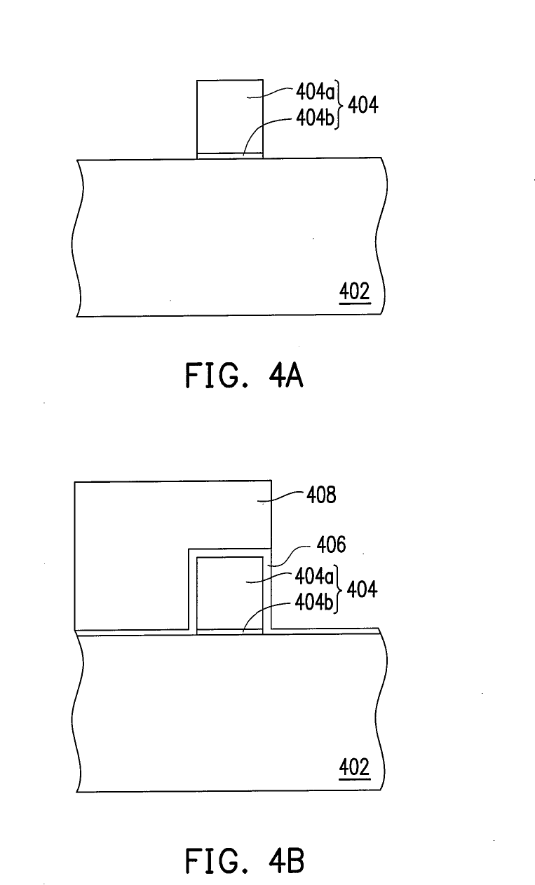

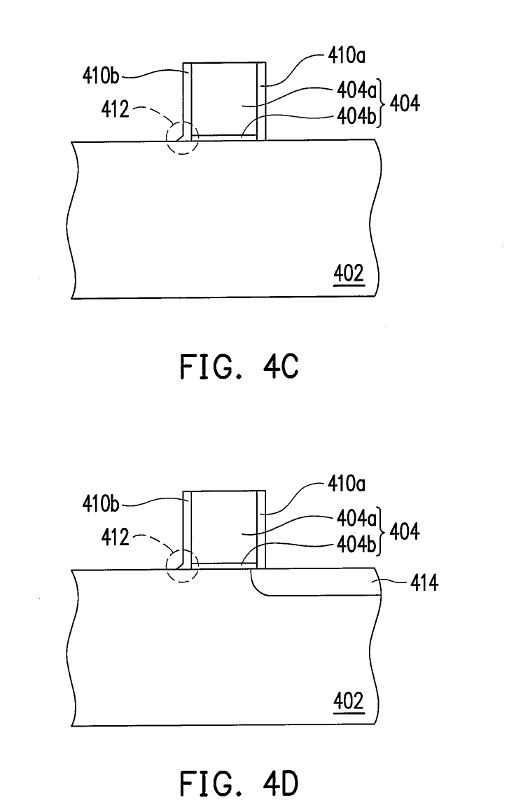

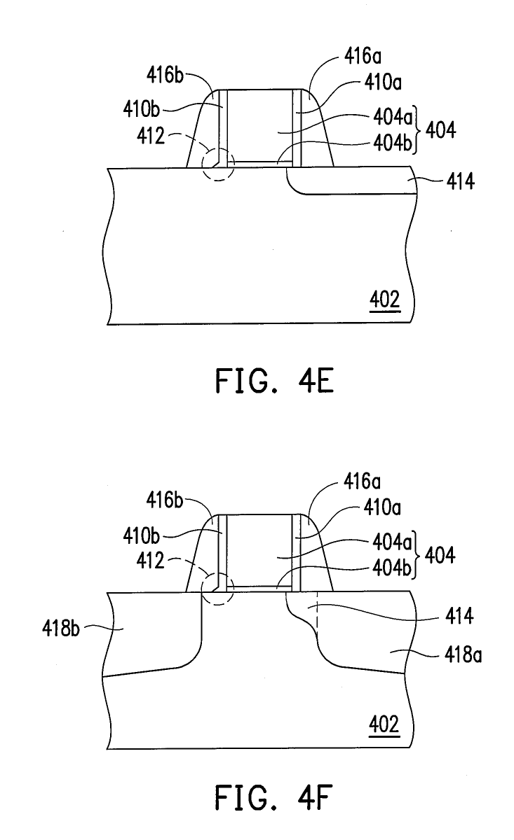

FIGS. 4A through 4F are schematic cross-sectional views illustrating the steps for fabricating an asymmetrical MOS transistor according to one embodiment of the present invention.

Referring to FIG. 4A, a substrate 402 is provided, and the substrate 402 is, for example, a silicon substrate. In this embodiment, the substrate 402 is, for example, a P-type substrate. Next, a gate structure 404 is formed on the substrate 402. The method for fabricating the gate structure 404 is, for example, forming a gate dielectric material layer (not shown) and a gate material layer (not shown) sequentially on the substrate 402. Herein, the material used for fabricating the gate dielectric material layer is, for example, silicon oxide or other suitable material, and the method for fabricating the same is, for example, a thermal oxidation process. The material used for fabricating the gate material layer is, for example, doped polysilicon or other suitable material and the method for fabricating the same is, for example, a chemical vapor deposition process. After the formation of the gate dielectric material layer and the gate material layer, a photolithography process and an etching process are performed to define the gate dielectric material layer and the gate material layer, forming a gate 404a and a gate dielectric layer 404b.

Thereafter, referring to FIG. 4B, an offset spacer material layer 406 is compliantly formed on the substrate 402 and the gate structure 404. The method used for forming the offset spacer material layer 406 is, for example, a chemical vapor deposition process. The offset spacer material layer 406 is, for example, a silicon oxide layer, a silicon nitride layer or other suitable dielectric material layer. Certainly, the offset spacer material layer 406 can be, for example, oxide/nitride/oxide (ONO) layer.

Referring to FIG. 4B, a photoresist layer 408 is formed over the substrate 402. The photoresist layer 408 covers a portion of the offset spacer material layer on one side of the gate structure 404 and the top of the gate structure 404.

Afterward, referring to FIG. 4C, an etch-back process is performed to remove the photoresist layer 408 and a portion of the offset spacer material layer 406 until the gate 404a and the surface of the substrate 402 are exposed to form the offset spacers 410a and 410b. Accordingly, the etch-back process is, for example, a reactive ion etching (RIE) process or other suitable etching process. It should be noted that, after the etch-back process is performed, residues of the offset spacer material layer, called footing, can be found at the junction connecting the offset spacer 410b and the substrate 402, as shown by the reference numeral 412 in FIG. 4C.

Thereafter, referring to FIG. 4D, a first ion implantation process is performed to the substrate 402 to form an extension region 414 below the offset spacer 410a in the substrate 402. It should be noted that, since the bottom of the offset spacer 410b extends to cover a portion of the surface of the substrate 402, as shown by the footing 412 in FIG. 4C, during the first ion implantation process, the footing 412 acts as a blocking layer to prevent the formation of an extension region below the offset spacer 410b in the substrate 402. As a result, only a doping region (not shown) is formed.

In the present embodiment, the extension region 414 is, for example, an doping region doped with N-type dopant, and the N-type dopant used is, for example, phosphorous (P) or arsenic (As). Further, the extension region 414 can be a heavily doping region which the doping concentration is between 5×10¹⁴ atoms/cm³ to 10¹⁸ atoms/cm³, and labeled as n⁺ doping region.

Thereafter, referring to FIG. 4E, a pair of spacers 416a and 416b are formed on the gate structure 404, covering the offset spacers 410a and 410b. The material used for fabricating the spacers 416a and 416b is, for example, silicon nitride or other suitable material. The method for fabricating the spacers 416a and 416b is, for example, forming a spacer material layer (not shown) to compliantly cover the gate 404a, the offset spacers 410a and 410b, and the substrate 402. Afterward, an anisotropic etching process is performed to remove a portion of the spacer material layer to form the spacers 416a and 416b.

Thereafter, referring to FIG. 4F, a second ion implantation process is performed to form a drain region 418a and a source region 418b in the substrate 402. Accordingly, the drain region 418a connects to the extension region 414. The drain region 418a, the source region 418b and the extension region 414 have the same dopant type, which is N-type dopant.

In the above-mentioned embodiment, the substrate 402 is a P-type substrate and the dopant type of the extension region 414, the drain region 418a and the source region 418b are n-type dopant, which are examples to illustrate the present invention; however, the invention is not limited to these examples. In one embodiment, the substrate 402 can be a P-type substrate, and the dopant type of the extension region 414, the drain region 418a and the source region 418b are doped with P-type dopants such as boron (B), and the extension region 414 is a p⁺ doping region.

Since the asymmetrical MOS transistor of the present invention has characteristics of a variable resistor and a transistor, a MOS fabrication process can be/is used to fabricate a variable resistor, rather than using the conventional process to fabricate a resistor such as a polysilicon resistor, a diffusion layer resistor or a well resistor.

Several embodiments are described in detail below to illustrate the application of the asymmetraical MOS transistor of the present invention. The asymmetraical MOS transistor of the present invention can be used in devices such as an inverter or a static random access memory (SRAM). However, the present invention is not limited to these embodiments. Anybody skilled in the art can apply the present invention in suitable devices accordingly, which will not be listed herein.

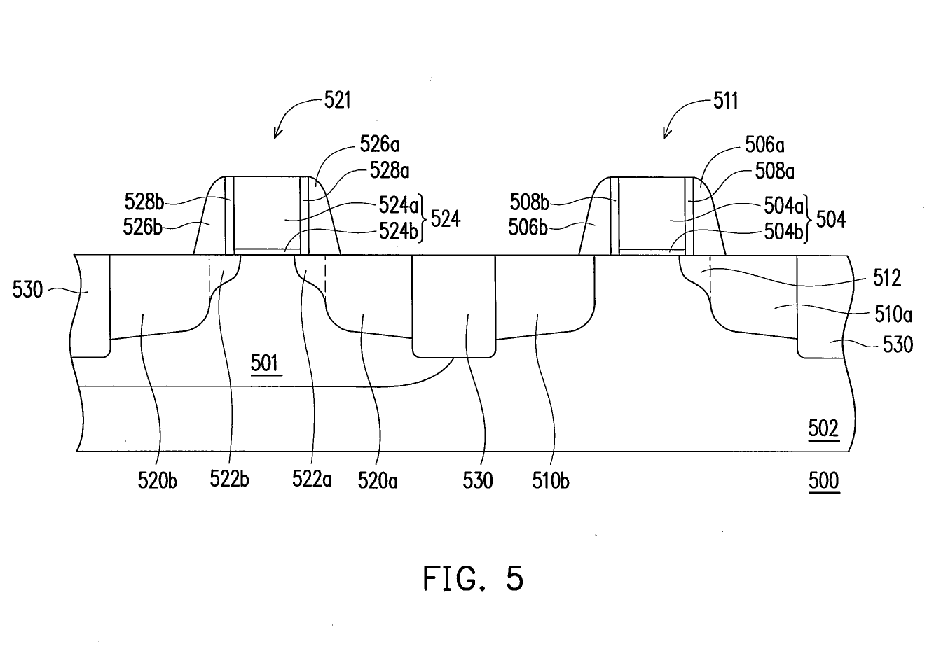

FIG. 5 is a schematic cross-sectional view illustrating an inverter according to one embodiment of the present invention.

Referring to FIG. 5, an inverter 500 is primarily formed by a P-type transistor 511 and an N-type transistor 521 that is serially connected to the P-type transistor 511. A device isolation structure 530 is disposed between the P-type transistor 511 and the N-type transistor 521. The device isolation structure 530 is, for example, a shallow trench isolation (STI) structure or other suitable isolation structures.

The P-type transistor 511 of the inverter 500 is the asymmetrical MOS transistor from the above-mentioned embodiment. The P-type transistor 511 includes an N-type substrate 502, a gate structure 504 formed by a gate 504a and a gate dielectric layer 504b, spacers 506a and 506b, offset spacers 508a and 508b, P-type drain-region 510a, P-type source 510b, and a P-type extension region 512. Herein, the extension region 512 can be, for example, p⁺ doping regions and the doping concentration is between 5×10¹⁴ atoms/cm³ to 10¹⁸ atoms/cm³. Additionally, since the same components such as the substrate 502, the gate 504a, the gate dielectric layer 504b, the spacers 506a and 506b, and the offset spacers 508a and 508b have been described in the above-mentioned embodiments, a detailed description thereof is omitted.

Furthermore, the N-type transistor 521 of the inverter 500 is a conventional MOS transistor (i.e. a symmetrical MOS transistor). The N-type transistor 521 includes a P-type well 501, a gate structure 524 formed by a gate 524a and a gate dielectric layer 524b, spacers 526a and 526b, offset spacers 528a and 528b, N-type drain region 520a, N-type source region 520b, and N-type extension regions 522a and 522b. In the above-mentioned embodiment, each component of the N-type transistor 521 is well known to the people skilled in the art, and is not described herein.

In the aforementioned embodiment, the P-type transistor of the inverter is the asymmetrical MOS transistor of the present invention while the N-type transistor is a conventional MOS transistor (i.e. a symmetrical transistor), which are examples to illustrate the present invention; however, the invention is not limited to these examples. In one embodiment, the P-type transistor of the inverter can be a conventional MOS transistor (i.e. a symmetrical MOS transistor) while the N-type transistor is the asymmetrical MOS transistor of the present invention.

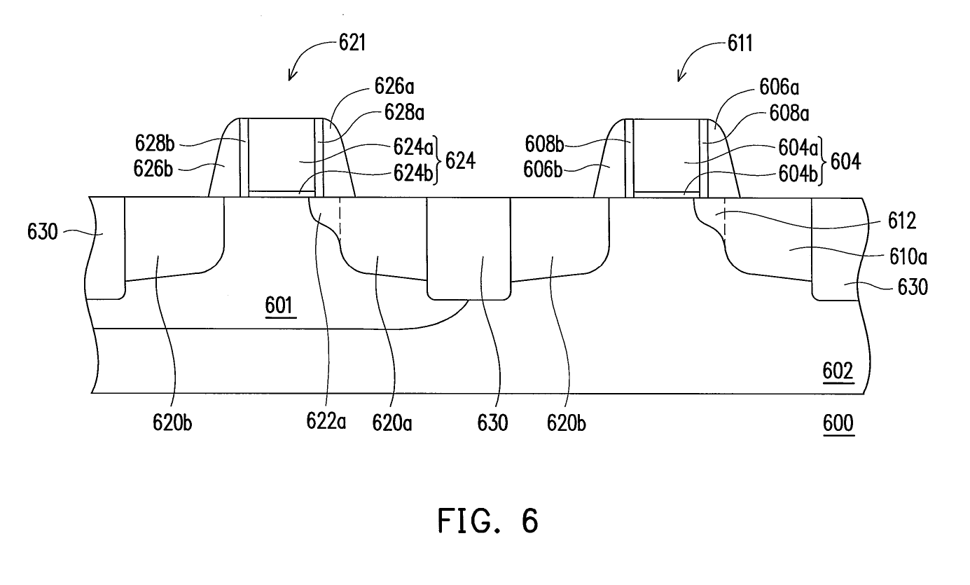

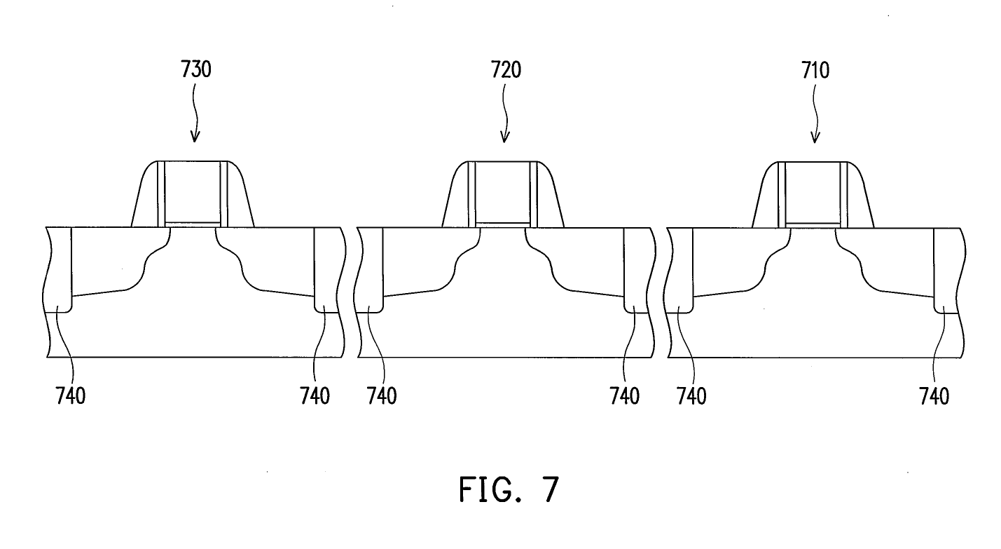

FIG. 6 is a schematic cross-sectional view illustrating an inverter according to another embodiment of the present invention.

Referring to FIG. 6, an inverter 600 in the present embodiment is similar to the inverter 500 in the embodiment of FIG. 5, except that a P-type transistor 611 and an N-type transistor 621 of the inverter 600 are both asymmetrical MOS transistors.

The P-type transistor 610 includes an N-type substrate 602, a gate structure 604 formed by a gate 604a and a gate dielectric layer 604b, spacers 606a and 606b, offset spacers 608a and 608b, P-type drain region 610a, P-type source region 610b, and a P-type extension region 612. Herein, the extension region 612 can be, for example, p⁺ doping regions and the doping concentration is between 5×10¹⁴ atoms/cm³ to 10¹⁸ atoms/cm³. Additionally, since the same components such as the substrate 602, the gate 604a, the gate dielectric layer 604b, the spacers 606a and 606b, and the offset spacers 608a and 608b have been described in the above-mentioned embodiments, a detailed description thereof is omitted.

Furthermore, the N-type transistor 621 includes a P-type well 601, a gate structure 624 formed by a gate 624a and a gate dielectric layer 624b, spacers 626a and 626b, offset spacers 628a and 628b, N-type drain region 620a, N-type source region 620b, and an N-type extension regions 622a. Herein, the extension region 622a can be, for example, n⁺ doping regions and the doping concentration is between 5×10¹⁴ atoms/cm³ to 10¹⁸ atoms/cm³. Additionally, since the same components such as the well 601, the gate 624a, the gate dielectric layer 624b, the spacers 626a and 626b, and the offset spacers 628a and 628b have been described in the above-mentioned embodiments, a detailed description thereof is omitted.

FIG. 7 is a schematic cross-sectional view of a SRAM according to an embodiment of the present invention.

Referring to FIG. 7, a SRAM is formed by six transistors (6T), which includes two load transistors (LT), two drive transistors (DT) and two access transistors (AT). In FIG. 7, only a load transistor 710, a drive transistor 720, and an access transistor 730 are illustrated. Further, device isolation structures 740 are disposed among the load transistor 710, the drive transistor 720, and the access transistor 730 to isolate these transistors. The device isolation structure 740 is, for example, a shallow trench isolation structure or other suitable isolation structure.

Accordingly/In the above-mentioned embodiment, the load transistor 710 is a P-type MOS transistor, while the drive transistor 720 and the access transistor 730 are N-type MOS transistors. Specifically, the load transistor 710 in the SRAM is an asymmetrical MOS transistor, while the drive transistor 720 and the access transistor 730 are conventional MOS transistors (i.e. symmetrical MOS transistors). Herein, the load transistor 710 is, for example, the asymmetrical MOS transistor shown in FIG. 1. Since the disposition of each component and the materials used for fabricating the same have been described in details in the above-mentioned embodiment, a detailed description thereof is omitted. Each component of the N-type transistor 720 and that of the access transistor 730 is well known to the people skilled in the art, and is thus not described herein.

As the load transistor of the above-mentioned SRAM is the asymmetrical MOS transistor of the present invention, the SRAM has the characteristics of a variable resistor and a transistor. Therefore, current leakage and resistance in the SRAM are reduced and ion gain is enhanced.

Another embodiment is described below to further illustrate the SRAM of the present invention.

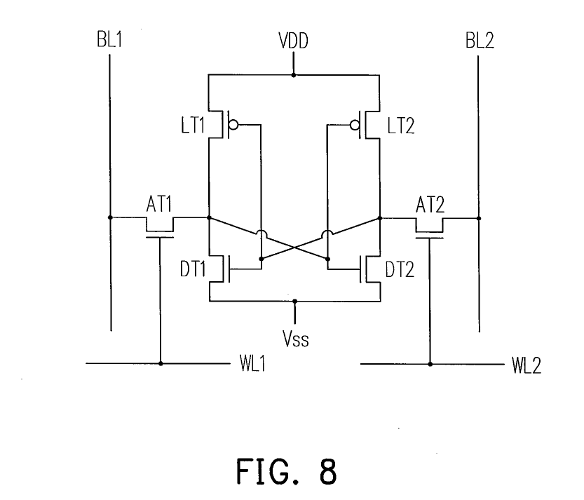

FIG. 8 is a schematic circuit diagram of a SRAM according to one embodiment of the present invention. This circuit includes a first word line (WL1), a second word line (WL2), a first bit line (BL1), a second bit line (BL2), a first access transistor (AT1), a second access transistor (AT2), a first load transistor (LT1), a first drive transistor (DT1), a second load transistor (LT2) and a second drive transistor (DT2). In this embodiment, the first access transistor (AT1), the second access transistor (AT2), the first drive transistor (DT1), and the second drive transistor (DT2) are N-type MOS transistors, while the first load transistor (LT1) and the second load transistor (LT2) are P-type MOS transistors. Specifically, the first load transistor (LT1) and the second load transistor (LT2) are the asymmetrical MOS transistors of the present invention. The first access transistor (AT1), the second access transistor (AT2), the first drive transistor (DT1), and the second drive transistor (DT2) are the conventional MOS transistors (i.e. symmetrical MOS transistors).

The gate of the first access transistor (AT1) is coupled to the first word line (WL1) and the first S/D region of the first access transistor (AT1) is coupled to the first bit line (BL1). The gate of the second access transistor (AT2) is coupled to the second word line (WL2) and the first S/D region of the second access transistor (AT2) is coupled to the second bit line (BL2). The gate of the first load transistor (LT1) is coupled to the second S/D region of the second access transistor (AT2). The first S/D region of the first load transistor (LT1) is coupled to the first voltage (e.g. source voltage V_{DD}) and the second S/D region of the first load transistor (LT1) is coupled to the second S/D region of the first access transistor (AT1). The gate and the first S/D region of the first drive transistor (DT1) are respectively coupled to the gate and the second S/D region of the first load transistor (LT1). The second S/D region of the first drive transistor (DT1) is coupled to the second voltage (e.g. ground voltage V_{SS}). The gate of the second load transistor (LT2) is coupled to the second S/D region of the first access transistor (AT1). The first S/D region of the second load transistor (LT2) is coupled to the first voltage (e.g. source voltage V_{DD}) and the second S/D region of the second load transistor (LT2) is coupled to the second S/D region of the second access transistor (AT2). The gate and the first S/D region of the second drive transistor (DT2) are respectively coupled to the gate and the second S/D region of the second load transistor (LT2). The second S/D region of the second drive transistor (DT2) is coupled to the second voltage (e.g. ground voltage V_{SS}).

In the above-mentioned embodiment, the load transistor of the SRAM is the asymmetrical MOS transistor of the present invention. Applying voltage from one terminal of the two S/D regions of the load transistor enables the load transistor to have the characteristics of a variable resistor and/or a transistor. Further, when the load transistor has the characteristics of a variable resistor, the resistance of the load transistor can be adjusted accordingly through adjusting the voltage applied to the gate.

In summary, the present invention has at least the following advantages:

1. The asymmetrical MOS transistor of the present invention helps the miniaturization of electronics products and improves the level of integration for the overall fabrication process.

2. The asymmetrical MOS transistor of the present invention lowers/reduces current leakage and resistance of the device and enhances ion gain.

3. The asymmetrical MOS transistor of the present invention can be fabricated using a MOS fabrication process to enable the device to have characteristics of a variable resistor and a transistor.

4. The asymmetrical MOS transistor of the present invention can be used in devices such as an inverter and a static random access memory and the asymmetrical MOS transistor of the present invention can reduce current leakage and resistance of devices and increase ion gain.

The present invention has been disclosed above in the embodiments, but is not limited to those. It is known to persons skilled in the art that some modifications and innovations may be made without departing from the spirit and scope of the present invention. Therefore, the scope of the present invention should be defined by the following claims.

What is claimed is:

1. An asymmetrical metal-oxide-semiconductor (MOS) transistor having characteristics of a variable resistor and a transistor, the asymmetrical MOS transistor comprising:
a substrate;
a gate structure disposed on the substrate, comprising a gate and a gate dielectric layer disposed between the gate and the substrate;
a pair of spacers respectively disposed on the sidewalls of the gate structure;
a pair of offset spacers respectively disposed between the gate structure and the spacers;
a source region and a drain region respectively disposed on the sides of the pair of spacers in the substrate; and
an extension region disposed in the substrate, and below one of the offset spacers and a portion of the gate structure, connecting to one of the source region and the drain region,
wherein the extension region is a heavily doping region.

2. The asymmetrical MOS transistor of claim 1, wherein the doping concentration of the extension region is between 5×10¹⁴ atoms/cm³ to 10¹⁸ atoms/cm³.

3. The asymmetrical MOS transistor of claim 1, wherein the pair of the offset spacers comprise silicon oxide layers, silicon nitride layers or oxide/nitride/oxide (ONO) layers.

4. A method for fabricating an asymmetrical MOS transistor having the characteristics of a variable resistor and a transistor, the method comprising:
forming a gate structure on a substrate, wherein the gate structure comprises a gate and a gate dielectric layer formed between the gate and the substrate;
forming a pair of offset spacers on the sidewalls of the gate structure and extending the bottom of one of the offset spacers to cover a portion of the surface of the substrate;
performing a first ion implantation process to form an extension region in the substrate on the sidewalls of the other offset spacer;
forming a pair of spacers on the gate structure to cover the offset spacers;
performing a second ion implantation process to form a source region and a drain region and connecting one of the source region and the drain region to the extension region,
wherein the extension region is a heavily doping region.

5. The method of claim 4, wherein the method for forming a pair of offset spacers comprises:
forming compliantly an offset spacer material layer on the substrate and the gate structure;
forming a photoresist layer to cover a portion of the offset spacer material layer on one side of the gate structure and the top of the gate structure; and
performing an etch-back process for removing the photoresist layer and a portion of the offset spacer material layer until the gate and the surface of the substrate are exposed to form the pair of the offset spacers.

6. The method of claim 4, wherein the doping concentration of the extension region is between 5×10¹⁴ atoms/cm³ to 10¹⁸ atoms/cm³.

7. The method of claim 4, wherein the pair of the offset spacers comprise silicon oxide layers, silicon nitride layers or oxide/nitride/oxide (ONO) layers.

8. An inverter, comprising:
a P-type transistor; and
an N-type transistor serially connected to the P-type transistor,
at least the P-type transistor or the N-type transistor is the asymmetrical MOS transistor as recited in claims 1 through 3.

9. A static random access memory (SRAM), comprising:
two access transistors;
two drive transistors; and
two load transistors,
wherein the load transistor is the asymmetrical MOS transistor as recited in claims 1 through 3.

10. The SRAM of claim 9, wherein the load transistors are P-type MOS transistors.

11. The SRAM of claim 9, wherein the access transistors are N-type MOS transistors.

12. The SRAM of claim 9, wherein the drive transistors are N-type MOS transistors.

13. A circuit for a static random access memory, the circuit comprising:
a first word line and a second word line;
a first bit line and a second bit line;
a first access transistor, wherein the gate of the first access transistor is coupled to the first word line and the first S/D region of the first access transistor is coupled to the first bit line;
a second access transistor, wherein the gate of the second access transistor is coupled to the second word line and the first S/D region of the second access transistor is coupled to the second bit line;
a first load transistor, wherein the gate of the first load transistor is coupled to the second S/D region of the second access transistor, the first S/D region of the first load transistor is coupled to a first voltage, and a second S/D region of the first load transistor is coupled to the second S/D region of the first access transistor, wherein the first load transistor is the asymmetrical MOS transistor as recited in claims 1 through 3;
a first drive transistor, wherein the gate of the first drive transistor is coupled to the second S/D region of the second access transistor, the first S/D region of the first drive transistor is coupled to the second S/D region of the first access transistor, and the second S/D region of the first drive transistor is coupled to a second voltage;
a second load transistor, wherein the gate of the second load transistor is coupled to the second S/D region of the first access transistor, the first S/D region of the second load transistor is coupled to the first voltage, and the second S/D region of the second load transistor is coupled to the second S/D region of the second access transistor, wherein the second load transistor is the asymmetrical MOS transistor as recited in claims 1 through 3; and
a second drive transistor, wherein the gate of the second drive transistor is coupled to the second S/D region of the first access transistor, the first S/D region of the second drive transistor is coupled to the second S/D region of the second access transistor, and the second S/D region of the second drive transistor is coupled to the second voltage;

14. The circuit of claim 13, wherein the first load transistor and the second load transistor are P-type MOS transistors.

15. The circuit of claim 13, wherein the first access transistor and the second access transistor are N-type MOS transistors.

16. The circuit of claim 13, wherein the first drive transistor and the second drive transistor are N-type MOS transistors.

17. The circuit of claim 13, wherein the first voltage is the source voltage and the second voltage is the ground voltage.
